(19) United States
(12) Patent Application Publication
(10) Pub. No.: US 2025/0364993 A1
(43) Pub. Date: Nov. 27, 2025

(54) SIGNAL TRANSMITTERS

(71) Applicant: Texas Instruments Incorporated, Dallas, TX (US)

(72) Inventors: Anirudh Rustagi, Cupertino, CA (US); Ashwin Ramachandran, Santa Clara, CA (US); Ramsin Ziazadeh, San Jose, CA (US)

(21) Appl. No.: 18/674,564

(22) Filed: May 24, 2024

(51) Int. Cl. H01L 27/12

(52) U.S. Cl. CPC H03K 19/094

(57) ABSTRACT

An example apparatus includes a first thin-film transistor (TFT) (308P) having a control terminal, a first current terminal, and a second current terminal, the second current terminal of the first TFT (308P) coupled to the supply terminal and the control terminal of the first TFT (308P) coupled to a first bias voltage, a second TFT (312P) having a control terminal, a first current terminal, and a second current terminal, the second current terminal of the second TFT (312P) coupled to the first current terminal of the first TFT (308P), the control terminal of the second TFT (312P) coupled to a second bias voltage, and the first current terminal of the second TFT (312P) coupled to the first output terminal (344), and a first capacitor (309P) coupled between the first input terminal (302) and the control terminal of the first TFT (308P).

### TECHNICAL FIELD

This description relates generally to electronic circuitry and, more particularly, to signal transmitters.

### BACKGROUND

A signal transmitter converts received information (e.g., a digital signal, an analog signal, etc.) into an electrical signal to be transmitted via a medium. For example, a signal transmitter may transmit information via a wired or wireless medium to a signal receiver. One type of signal transmitter is a source-series-terminated (SST) transmitter that provides a low power solution that can support a range of signal voltages.

### SUMMARY

For signal transmitters a transmitter circuit includes a supply terminal. The transmitter circuit includes a first input terminal; a first output terminal; a ground terminal; a first thin-film transistor having a control terminal, a first current terminal, and a second current terminal, the second current terminal of the first TFT coupled to the supply terminal and the control terminal of the first TFT coupled to a first voltage; a second TFT having a control terminal, a first current terminal, and a second current terminal, the second current terminal of the second TFT coupled to the first current terminal of the first TFT, the control terminal of the second TFT coupled to a second voltage, and the first current terminal of the second TFT coupled to the first output terminal; a third TFT having a control terminal, a first current terminal, and a second current terminal, the second current terminal of the third TFT coupled to the ground terminal and the control terminal of the third TFT coupled to a third voltage and coupled to the first input terminal; a fourth TFT having a control terminal, a first current terminal, and a second current terminal, the second current terminal of the fourth TFT coupled to the first current terminal of the third TFT, the control terminal of the fourth TFT coupled to a fourth voltage, and the first current terminal of the fourth TFT coupled to the first output terminal. The transmitter circuit includes a first capacitor coupled between the first input terminal and the control terminal of the first TFT.

For signal transmitters an apparatus includes a receiver circuit to receive at least two video input signals and to convert the two video input signals to a single video signal; a transmitter to transmit the single video signal, the transmitter including: a supply terminal; a first input terminal coupled to the receiver circuit to receive the single video signal; a first output terminal; a ground terminal; a first thin-film transistor having a control terminal, a first current terminal, and a second current terminal, the second current terminal of the first TFT coupled to the supply terminal and the control terminal of the first TFT coupled to a first voltage; a second TFT having a control terminal, a first current terminal, and a second current terminal, the second current terminal of the second TFT coupled to the first current terminal of the first TFT, the control terminal of the second TFT coupled to a second voltage, and the first current terminal of the second TFT coupled to the first output terminal; a third TFT having a control terminal, a first current terminal, and a second current terminal, the second current terminal of the third TFT coupled to the ground terminal and the control terminal of the third TFT coupled to a third voltage and coupled to the first input terminal; a fourth TFT having a control terminal, a first current terminal, and a second current terminal, the second current terminal of the fourth TFT coupled to the first current terminal of the third TFT, the control terminal of the fourth TFT coupled to a fourth voltage, and the first current terminal of the fourth TFT coupled to the first output terminal; a first capacitor coupled between the first input terminal and the control terminal of the first TFT; and a second capacitor coupled between the first input terminal and the control terminal of the third TFT.

For signal transmitters a circuit includes a first diode connected transistor to supply a first voltage; and a second diode connected transistor coupled to the first diode connected transistor, the second diode connected transistor to supply a second voltage; a third diode connected transistor to supply a third voltage; and a fourth diode connected transistor coupled to the third diode connected transistor, the fourth diode connected transistor to supply a fourth voltage. The apparatus includes a transmitter including: a supply terminal; a first input terminal; a first output terminal; a ground terminal; a first thin-film transistor having a control terminal, a first current terminal, and a second current terminal, the second current terminal of the first TFT coupled to the supply terminal and the control terminal of the first TFT coupled to the first voltage and coupled to the first input terminal; a second TFT having a control terminal, a first current terminal, and a second current terminal, the second current terminal of the second TFT coupled to the first current terminal of the first TFT, the control terminal of the second TFT coupled to the second voltage, and the first current terminal of the second TFT coupled to the first output terminal; a third TFT having a control terminal, a first current terminal, and a second current terminal, the second current terminal of the third TFT coupled to the ground terminal and the control terminal of the third TFT coupled to the third voltage and coupled to the first input terminal; and a fourth TFT having a control terminal, a first current terminal, and a second current terminal, the second current terminal of the fourth TFT coupled to the first current terminal of the third TFT, the control terminal of the fourth TFT coupled to the fourth voltage, and the first current terminal of the fourth TFT coupled to the first output terminal. Other examples are described.

### BRIEF DESCRIPTION OF THE DRAWINGS

FIG. 1 illustrates an example environment in which a transmitter in accordance with the methods and apparatus described herein may operate.

FIG. 2 is a block diagram of an example integrated circuitry for transmitting video signals.

FIG. 3 illustrates an example transmitter coupled to an example bias circuitry implemented according to the methods and apparatus described herein.

FIG. 4 is another implementation of a transmitter.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

High speed and high swing transmitter designs are useful in providing desired signal to noise ratio (SNR) characteristics for communication media that exhibits high channel loss to support low bit error rates (BER). An example high speed/high swing transmitter may operate at 20 gigabit per second (Gbps) or more and may output a signal that swings between 1.8V and 5V. Such high speed/high swing transmitters may be well suited for full duplex communications such as flat panel display (FPD) link systems which are used in display systems in automotive applications, wireless systems, and other applications where significant noise is present within communication channels and require low bit error rate (BER). High swing transmitters are useful for multi-level modulation schemes such as phase amplitude modulation 3 (PAM3), PAM4, quadrature phase-shift keying (QPSK), quadrature amplitude modulation (QAM), etc.

Increase in the transmitted signal swing is typically achieved by raising the power supply which introduces a concern as transmitters may be limited by the reliability limits of thin oxide complementary metal-oxide semiconductor (CMOS) devices that are often used in such transmitters. For example, such CMOS devices include specified safe operating voltage (SOV) limits that restrict the maximum voltage that may be handled by the device and, thus, limit the maximum voltage that may be provided to support a high swing transmitter.

Signal transmitters described herein utilize a series combination of multiple thin oxide devices to achieve desired signal swing while complying with the SOV of each individual thin oxide device without compromising on the operating speed of the transmitter. The series combination of thin oxide devices may be referred to as a stack. The thin oxide devices may utilize a data dependent gate modulation biasing scheme to maintain their safe operating region. In some examples, additional power efficiency may be provided by taking advantage of input logic signaling in Pulse Amplitude Modulation (PAM) modes.

The signal transmitters described herein utilize N thin oxide devices that are stacked to meet a desired high swing output. For example, the differential peak-to-peak voltage output may be determined by

$$\frac{4 N \times SOV}{3} ,$$

where SOV is safe operating voltage of the thin oxide devices. For example, if the SOV is 1 volt, 2 thin oxide devices can provide a maximum output swing of 2.66 V, 3 thin oxide device can provide a maximum output swing of 4.00 V, 4 thin oxide devices can provide a maximum output swing of 5.33 V, 5 thin oxide devices can provide a maximum output swing of 6.66 V, and 6 thin oxide devices can provide a maximum output swing of 8.00 V.

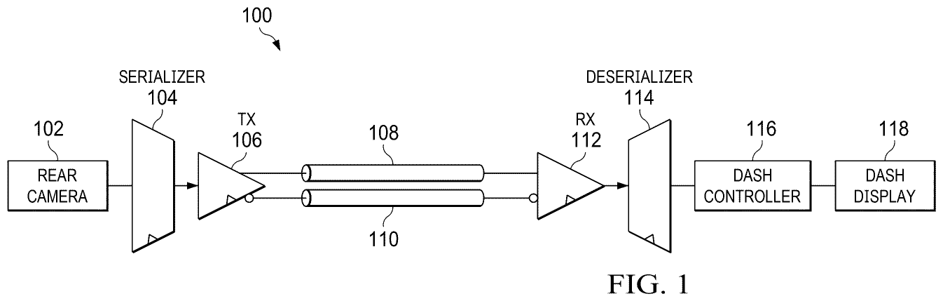

FIG. 1 illustrates an example environment 100 in which a transmitter 106 in accordance with the methods and apparatus described herein may operate. The example environment 100 is an automotive environment. Alternatively, the transmitter 106 may be utilized in any type of environment that utilizes signal transmission.

The example environment 100 includes a rear camera 102 coupled to a serializer 104, which is coupled to the transmitter 106, which is coupled to a bidirectional transmission channel having a first transmission channel 108 and a second transmission channel 110, which are coupled to a receiver 112, which is coupled to a deserializer 114, which is coupled to a dash controller 116, which is coupled to a dash display 118.

The example rear camera 102 is a video recording device located at the rear end of a vehicle to capture images/video of the area behind/around a vehicle. The example rear camera 102 utilizes a high speed digital interface known as flat panel display (FPD) link. Alternatively, any other type of output interface may be utilized. The rear camera 102 outputs multiple parallel signals to represent the captured images/video. The serializer 104 converts the parallel signals into a serial signal for transmission by the transmitter 106.

The transmitter 106 transmits the serialized signal via the transmission channels 108, 110. The example transmitter 106 supports high speed/high swing operation by utilizing a stack of thin oxide transistors to increase the output swing and also ensure safe operating voltage of any transistor is not violated inside the transmitter 106 without compromising on operating speed. Further details of example implementation details of the transmitter 106 are described below. By supporting high swing operation, the transmitter 106 is well-suited for operation in noisy environments in which the transmission channels 108, 110 may experience significant signal loss during a transmission. For example, long wires from the rear of a vehicle to the front of the vehicle may be exposed to many noise sources from other components of the vehicle and from sources external to the vehicle. While FIG. 1 illustrates two wires connected to the transmitter (e.g., for transmission of a positive signal and negative signal), the transmitter 106 may be utilized with any number of transmission channels and any type of combination of types of transmission channels (e.g., wired, wireless, etc.).

The receiver 112 receives the signals transmitted by the transmitter 106 and converts the signal (e.g., a voltage signal) into a digital signal that is deserialized by the deserializer 114. According to the illustrated example, the data signal from the deserializer 114 is received by the dash controller 116 and the video/images from the rear camera 102 is displayed on the dash display 118. For example, the dash controller 116 and the dash display 118 may be integrated into a vehicle multimedia system.

While FIG. 1 illustrates an automotive example for video transmission, the signal transmitters described herein may be utilized in any type of environment and any type of signal swing can be achieved through the stack.

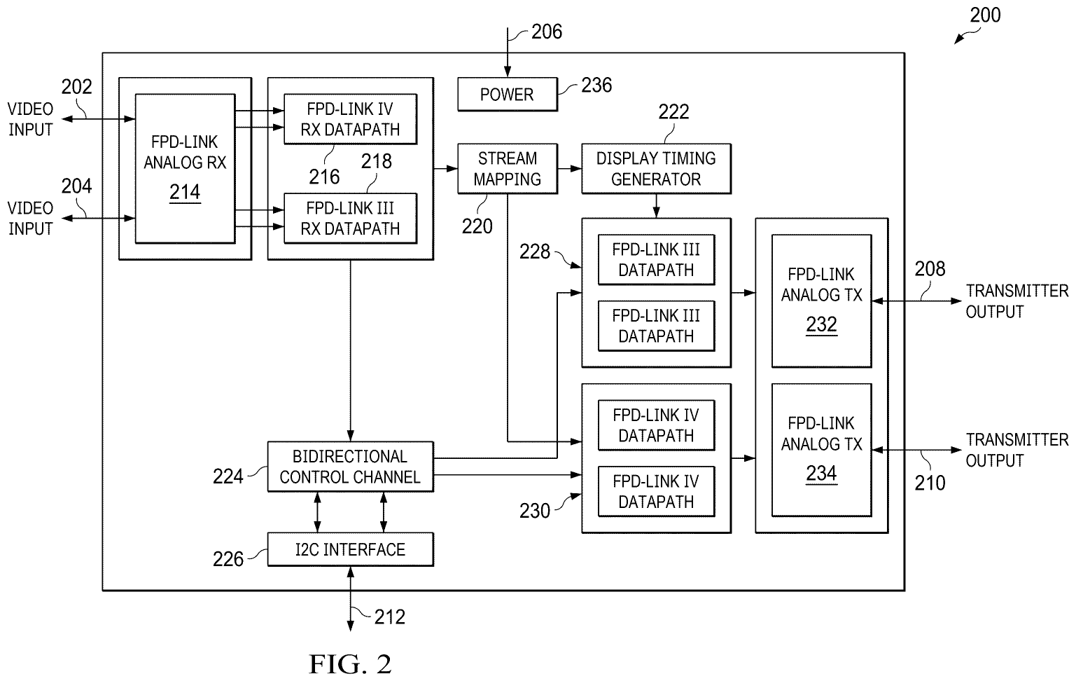

FIG. 2 is a block diagram of an example integrated circuitry 200 for transmitting video signals (e.g., a video signal from the rear camera 102). The example integrated circuitry includes a first video input terminal 202, a second video input terminal 204, a power input terminal 206, a first transmitter output terminal 208, a second transmitter output terminal 210, and a programming interface terminal 212.

The video input interfaces 202, 204 are coupled to an FPD-link analog receiver 214 to receive analog signals from video sources (e.g., cameras). The example integrated circuitry 200 includes a first datapath 216 for handling FPD-Link IV signals and a second datapath 218 for handling FPD-Link III signals. The video signals are output to a stream mapping circuitry 220, which outputs stream mapping information to a display timing generator circuitry 222, and a bidirectional channel control circuitry 224, which may be programmed based on signals received via the programming interface terminal 212 and received by an inter-integrated circuitry (I2C) interface 226.

An FPD-Link III datapath 228 receives control information from the bidirectional control channel 224 and video data with timing information from the display timing generator circuitry 222. An FPD-Link IV datapath 230 receives the stream mapped video from the stream mapping circuitry 220 and control information from the bidirectional control channel 224.

Regardless of the datapath 228, 230, a first transmitter 232 receives the data corresponding to the video input 202 and a second transmitter 234 receives the data corresponding to the video input 204. The transmitters 232, 234 are implemented according to the methods and apparatus described herein to support high-speed/high swing data transmission via the transmitter outputs 208, 210.

The example integrated circuitry 200 is powered by a supply coupled to the power input terminal 206 and managed by the power control circuitry 236.

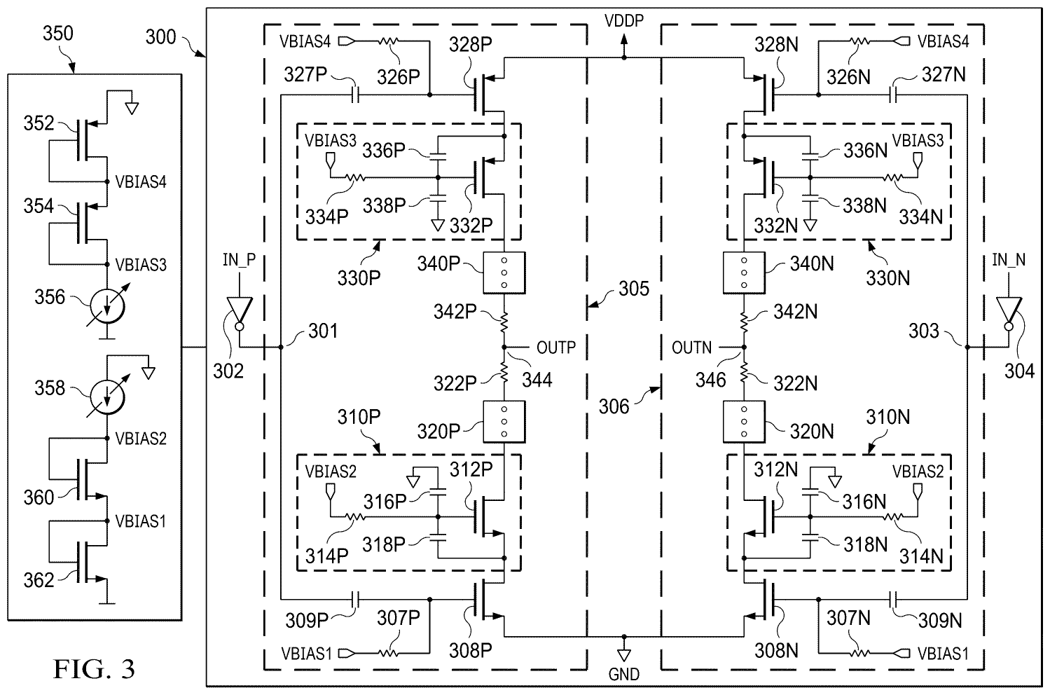

FIG. 3 illustrates an example transmitter 300 coupled to an example bias circuitry implemented according to the methods and apparatus described herein. The transmitter 300 may be utilized to implement one or more of the transmitter 106 of FIG. 1 and the transmitters 232, 234 of FIG. 3.

The example transmitter 300 includes a positive input terminal 302 and a negative input terminal 304. The positive input terminal 302 is coupled to an input buffer 301, which is coupled to positive-side transmitter circuitry 305. The negative input terminal 304 is coupled to an input buffer 303, which is coupled to negative-side transmitter circuitry 306. The example input buffer 301 and the example input buffer 303 are inverting input buffers, but non-inverting buffers would be utilized in other implementations.

The example positive transmitter circuitry 305 includes the same components as the negative transmitter circuitry 306. Accordingly, the matching components have been labeled with the same part number but using the postfix P and N. Furthermore, the matching components are described a single time using the general part number for conciseness.

The transmitter circuitry 305, 306 each include an alternating current (AC) coupling capacitor 309 coupled to the input buffer 301 or the input buffer 303, respectively, to facilitate connection of the transmitter circuitry 305, 306 directly to core digital input signals. The AC coupling capacitor 309 helps to level shift the signals from digital core signal level to a high supply domain signal level. The transmitter circuitry 305, 306 each include a first resistor 307, a first transistor 308, and a capacitor 309. The transmitter circuitry 305, 306 includes a first gate modulated transistor circuitry 310 that includes a transistor 312, a resistor 314, a first capacitor 316, and a second capacitor 318. The transmitter circuitry 305, 306 may include any number of additional gate modulated transistor circuits (stacked transistor circuitry depending on output voltage swing required) represented by block 320. The transmitter circuitry 305, 306 further includes a first output resistor 322.

The transmitter circuitry 305, 306 each include a second resistor 326, an AC coupling capacitor 327, and a second transistor 328. The transmitter circuitry 305, 306 includes a second gate modulated transistor circuitry 330 that includes a transistor 333, a resistor 334, a first capacitor 336, and a second capacitor 338. The transmitter circuitry 305, 306 may include any number of additional gate modulated transistor circuits (stacked transistor circuitry depending on output voltage swing required) represented by block 340. The transmitter circuitry 305, 306 further includes a second output resistor 342.

The positive transmitter circuitry 305 includes a positive output terminal 344. The negative transmitter circuitry 306 includes a negative output terminal 346. While the example of FIG. 3 includes a positive input that is output as the positive output and a negative input that is output as the negative input, any arrangement of inputs and outputs may be implemented (e.g., by including additional inverting components).

The AC coupling capacitor 309 includes a first terminal and a second terminal. The first terminal of the AC coupling capacitor 309 is coupled to the input buffer 301, 304 respectively. The first transistor 308 includes a control terminal, a first current terminal and a second current terminal. The control terminal of the first transistor is coupled to the second terminal of the capacitor 309, the first current terminal is coupled to a ground terminal. The first resistor 307 includes a first terminal connected to a first signal vbias1 and a second terminal coupled to the control terminal of the first transistor 308.

For each instance of the gate modulated transistor circuitry 310, the transistor 312 includes a control terminal, a first current terminal, and a second current terminal. The resistor 314 includes a first terminal couped to a second signal vbias2 and a second terminal. The first capacitor 316 includes a first terminal coupled to a ground terminal, and a second terminal. The second capacitor 318 includes a first terminal coupled to the first current terminal of the transistor 312 and the second current terminal of the transistor 308. The second terminal of the capacitor 316 and the second terminal of the capacitor 318 are coupled to the second terminal of the resistor 314 and the control terminal of the transistor 312 to form a capacitor divider. The second current terminal of the transistor 312 is coupled to the block 320 (e.g., to a current terminal of a transistor corresponding to transistor 312 in the block 320). Alternatively, if there are no additional transistors stacked, then the second terminal of the transistor 312 is coupled to the first output resistor 322.

The capacitor dividers (e.g., capacitors 316, 318 and 336, 338) modulate the gate voltage/control terminal of the stacked transistors (e.g., 312, 332) to ensure safe operating voltage for thin oxide devices.

The first output resistor 322 includes a first terminal coupled to the block 320 (or the second current terminal of the transistor 312) and a second terminal coupled to the respective output terminal 344, 346.

The AC coupling capacitor 327 includes a first terminal and a second terminal. The first terminal of the AC coupling capacitor 327 is coupled to the input buffer 301, 303, respectively.

The second transistor 328 includes a control terminal, a first current terminal and a second current terminal. The control terminal of the first transistor is coupled to the second terminal of the AC coupling capacitor 327, the first current terminal is coupled to a ground terminal. The second resistor 326 includes a first terminal connected to a first signal vbias4 and a second terminal coupled to the control terminal of the second transistor 328.

For each instance of the gate modulated transistor circuitry 330, the transistor 332 includes a control terminal, a first current terminal, and a second current terminal. The resistor 334 includes a first terminal couped to a second signal vbias3 and a second terminal. The first capacitor 336 includes a first terminal coupled to a ground terminal, and a second terminal. The second capacitor 338 includes a first terminal coupled to the first current terminal of the transistor 332 and the second current terminal of the transistor 328. The second terminal of the capacitor 336 and the second terminal of the capacitor 338 are coupled to the second terminal of the resistor 334 and the control terminal of the transistor 332 to form a capacitor divider. The second current terminal of the transistor 332 is coupled to the block 340 (e.g., to a current terminal of a transistor corresponding to transistor 332 in the block 340). Alternatively, if there are no additional transistors stacked, then the second terminal of the transistor 332 is coupled to the second output resistor 342.

The second output resistor 342 includes a first terminal coupled to the block 340 (or the second current terminal of the transistor 332) and a second terminal coupled to the respective output terminal 344, 346.

The number of instances of the gate modulated transistor circuits may be selected to achieve a desired output voltage swing (e.g., by more gate modulated transistor circuits that are included increases the maximum voltage and, thus, the voltage swing of the transmitter 300). Accordingly, thin film transistors may be utilized even if the SOV of the transistors is less than the desired output voltage characteristics.

The bias signals for the transmitter 300 are supplied by an example bias generation circuitry 350. The example bias generation circuitry 350 includes a first transistor 352, a second transistor 352, a first variable current source 356, a second variable current source 358, a third transistor 360, and a fourth transistor 362.

The transistor 352 includes a control terminal, a first current terminal coupled to a supply terminal, and a second current terminal coupled to the control terminal. The transistor 354 includes a control terminal, a first current terminal coupled to the second current of the transistor 352, and a second current terminal coupled to the control terminal. The variable current source 356 includes a first terminal coupled to the second current terminal of the transistor 352 and a second terminal coupled to a ground terminal. The vbias4 signal is supplied to the transmitter 300 at the second current terminal of the transistor 352 and the vbias3 signal is supplied to the transmitter 300 at the second current terminal of the transistor 354.

The variable current source 358 includes a first terminal coupled to a supply terminal and a second terminal. The transistor 360 includes a control terminal, a first current terminal coupled to the second terminal of the variable current source 358 and the control terminal, and a second current terminal. The transistor 362 includes a control terminal, a first current terminal coupled to the second current terminal of the transistor 360 and the control terminal of the transistor 362, and a second current terminal coupled to a ground terminal. The vbias2 signal is supplied to the transmitter 300 at the first current terminal of the transistor 360 and the vbias1 signal is supplied to the transmitter 300 at the first current terminal of the transistor 362.

The variable current sources 356 and 358 may be manually controlled (e.g., by a manufacturer to tune the bias signals for a particular application). Alternatively, the variable current sources 356 and 358 may be controlled by a processor that monitors the operation of the circuit to compensate for changes in the operation and environment of the circuit (e.g., based on circuit load, environmental temperature, etc.

The value of resistor 322 and sizing of the transistors 312 and 308 are selected such that when the OUT_P goes low and current flows through them, the resistance of the resistor 322 plus the resistors of transistor 312 plus the resistance of transistor 309 plus the resistance of transistors within the block 320 is equal to 50 ohms. Similarly, the value of the resistor 342 and sizing of the transistors 328 and 332 are selected such that when the OUT_P goes high and current flows through them, the resistance of the resistor 342 plus the resistance of transistors within the block 340 plus the resistance of the transistor 332 plus the resistance of the transistor 328 is equal to 50 ohms. Similarly principles may be applied for the transistors in the negative transmitter circuitry 306.

In the example of FIG. 3, the transistors 328, 332, 352, and 354 are p-channel metal-oxide semiconductor field-effect transistors (MOSFETs) and the transistors 308, 312, 360, and 362 are n-channel MOSFETS. Alternatively, some or all of the n-channel MOSFETS may be p-channel MOSFETS and some or all of the p-channel MOSFETS may be n-channel MOSFETS. Some or all of the transistors may be field-effect transistors (FETs), insulated-gate bipolar transistors (IGBTs), junction field effect transistors (JFETs), NPN bipolar junction transistors (BJTs) Furthermore, the transistors may be implemented in/over a silicon substrate (Si), a silicon carbide substrate (SiC), a gallium nitride substrate (GaN) or a gallium arsenide substrate (GaAs).

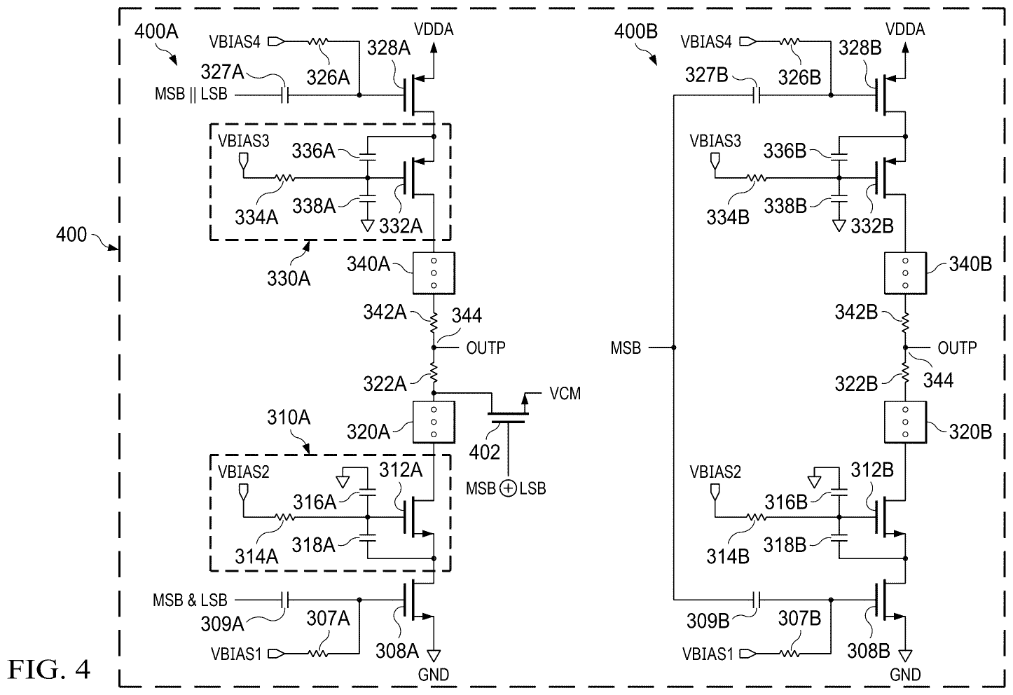

FIG. 4 illustrates an example implementation of transmitter circuitry 400 that is a variation of the transmitter circuitry 305 and the transmitter circuitry 306 of FIG. 3. While the transmitter circuitry 400 is illustrated as the positive-side of the transmitter (e.g., similar to the transmitter circuitry 305), the transmitter circuitry 400 could alternatively implement the negative-side of the transmitter (e.g., similar to the transmitter circuitry 306). The example transmitter circuitry 400 of FIG. 4 is configured to facilitate reduced power consumption in PAM4 operation. As compared with the transmitter circuitry 305 of FIG. 3, the transmitter circuitry 400 of FIG. 4 separates the circuitry into two portions: transmitter circuitry 400A and transmitter circuitry 400B. The transmitter circuitry 400A is coupled to a signal of the most significant bits and least significant bits of the input signal and the transmitter circuitry 400B is coupled to the most significant bit.

The transmitter circuitry 400A includes the same components as the transmitter circuitry 305 of FIG. 3 with the addition of the transistor 402 and excluding the input buffer 301. The transmitter circuitry 400B also includes the same components as the transmitter circuitry 305 of FIG. 3. For clarity of illustration, the components of the transmitter circuitry 400A include part numbers with the letter A and the components of the transmitter circuitry 400B include part numbers with the B.

In the transmitter circuitry 400A, the AC coupling capacitor 309 is coupled to the most significant bits AND′d with the least significant bits and the AC coupling capacitor 327 is AND′d with the most significant bits OR′d with the least significant bits. The transmitter circuitry 400A additionally includes transistor 402. Transistor 402 includes a control terminal, a first current terminal and a second current terminal. The control terminal of the transistor 402 is coupled to the most significant bits XOR'd with the least significant bits of the input signal. The transistor 402 is added to help with reduction in power during PAM4 operation.

The first current terminal of the transistor 402 is coupled to a common mode voltage supply. The second current terminal of the transistor 402 is coupled to the first terminal of the resistor 322.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for case of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. A transmitter circuit (300) comprising:
a first thin-film transistor (TFT) (308P) having a control terminal, a first current terminal, and a second current terminal, the second current terminal of the first TFT (308P) coupled to ground and the control terminal of the first TFT (308P) coupled to a first voltage;
a second TFT (312P) having a control terminal, a first current terminal, and a second current terminal, the second current terminal of the second TFT (312P) coupled to the first current terminal of the first TFT (308P), the control terminal of the second TFT (312P) coupled to a second voltage, and the first current terminal of the second TFT (312P) coupled to a first output terminal (344);
a third TFT (328P) having a control terminal, a first current terminal, and a second current terminal, the second current terminal of the third TFT (328P) coupled to a voltage supply and the control terminal of the third TFT (328P) coupled to a third voltage and coupled to the first input terminal (302);
a fourth TFT (332P) having a control terminal, a first current terminal, and a second current terminal, the second current terminal of the fourth TFT (332P) coupled to the first current terminal of the third TFT (328P), the control terminal of the fourth TFT (332P) coupled to a fourth voltage, and the first current terminal of the fourth TFT (332P) coupled to the first output terminal (344) and
a first capacitor (309P) coupled between the first input terminal (302) and the control terminal of the first TFT (308P).

2. The transmitter circuit (300) of claim 1, further:
a fifth TFT having a control terminal, a first current terminal, and a second current terminal, the second current terminal coupled to the voltage supply, the control terminal of the fifth TFT coupled to the second input terminal (304), and the first current terminal of the third TFT (328P) coupled to the first current terminal of the second TFT (312P) and the first output terminal (344).

3. The transmitter circuit (300) of claim 1, further including a second capacitor (327P) coupled between the first input terminal (302) and the control terminal of the third TFT (328P).

4. The transmitter circuit (300) of claim 1, further including a buffer (301P) coupled between the first input terminal (302) and the first capacitor. (309P).

5. The transmitter circuit (300) of claim 4, wherein the buffer (301P) is an inverter.

6. The transmitter circuit (300) of claim 1, further including:
a fifth TFT (308N) having a control terminal, a first current terminal, and a second current terminal, the second current terminal of the fifth TFT (308N) coupled to ground and the control terminal of the fifth TFT (308N) coupled to a fifth voltage and coupled to the second input terminal (304); and
a sixth TFT (312N) having a control terminal, a first current terminal, and a second current terminal, the second current terminal of the sixth TFT (312N) coupled to the first current terminal of the fifth TFT (308N), the control terminal of the sixth TFT (312N) coupled to a sixth voltage, and the first current terminal of the sixth TFT (312N) coupled to a second input terminal (304).

7. The transmitter circuit (300) of claim 1, further including:
a fifth TFT (represented in 320P) having a control terminal, a first current terminal, and a second current terminal, the control terminal of the fifth TFT coupled to a fifth voltage, the first current terminal of the fifth TFT coupled to the first output terminal (344), and the second current terminal of the fifth TFT coupled to the first current terminal of the second TFT (312P); and
a sixth TFT (represented 340P) having a control terminal, a first current terminal, and a second current terminal, the control terminal of the sixth TFT coupled to a bias voltage, the first current terminal of the sixth TFT coupled to the second current terminal of the fourth TFT (332P), and the second current terminal of the sixth TFT coupled to the first output terminal (344).

8. The transmitter circuit (300) of claim 1, further including:
a resistor (307P) having a first terminal and a second terminal, the first terminal of the resistor (307P) coupled to the first voltage and the second terminal of the resistor (307P) coupled to the control terminal of the first TFT (308P);
a first capacitor (318P) having a first terminal and a second terminal, the first terminal of the first capacitor (318P) coupled to the second current terminal of the second TFT (312P); and
a second capacitor (316P) having a first terminal and a second terminal, the first terminal of the second capacitor (316P) coupled to the second terminal of the resistor (314P) and the second terminal of the first capacitor (318P), the second terminal of the second capacitor (316P) coupled to the ground terminal.

9. An apparatus comprising:
receiver circuit (214);
a transmitter (232) including:
a supply terminal;
a first input terminal (302) coupled to the receiver circuit (214);
a first output terminal (344);
a ground terminal;
a first thin-film transistor (TFT) (308P) having a control terminal, a first current terminal, and a second current terminal, the second current terminal of the first TFT (308P) coupled to the supply terminal and the control terminal of the first TFT (308P) coupled to a first voltage;
a second TFT (312P) having a control terminal, a first current terminal, and a second current terminal, the second current terminal of the second TFT (312P) coupled to the first current terminal of the first TFT (308P), the control terminal of the second TFT (312P) coupled to a second voltage, and the first current terminal of the second TFT (312P) coupled to the first output terminal (344);
a third TFT (328P) having a control terminal, a first current terminal, and a second current terminal, the second current terminal of the third TFT (328P) coupled to the ground terminal and the control terminal of the third TFT (328P) coupled to a third bias voltage and coupled to the first input terminal (302);
a fourth TFT (332P) having a control terminal, a first current terminal, and a second current terminal, the second current terminal of the fourth TFT (332P) coupled to the first current terminal of the third TFT (328P), the control terminal of the fourth TFT (332P) coupled to a fourth voltage, and the first current terminal of the fourth TFT (332P) coupled to the first output terminal (344);
a first capacitor (309P) coupled between the first input terminal (302) and the control terminal of the first TFT (308P); and
a second capacitor (327P) coupled between the first input terminal (302) and the control terminal of the third TFT (328P).

10. The apparatus as defined in claim 9, wherein the receiver circuit (214) includes a serializer.

11. The apparatus as defined in claim 9, wherein the receiver circuit (214) is a flat panel display link receiver circuit.

12. The apparatus as defined in claim 9, further including a flat panel display link datapath to couple the receiver circuit (214) to the transmitter (232).

13. The apparatus as defined in claim 9, further including a camera coupled to the receiver circuit (214).

14. The apparatus as defined in claim 13, further including:
a receiver (112) coupled to the transmitter (232) to receive a single video signal; and
a display (118) to display a video representative of the single video signal.

15. An apparatus comprising:
a bias circuit (350) including:
a first diode connected transistor (362) to supply a first voltage; and
a second diode connected transistor (360) coupled to the first diode connected transistor (362), the second diode connected transistor (360) to supply a second voltage;
a third diode connected transistor (354) to supply a third voltage; and
a fourth diode connected transistor (352) coupled to the third diode connected transistor (354), the fourth diode connected transistor (352) to supply a fourth voltage; and
a transmitter (300) including:
a supply terminal;
a first input terminal (302);
a first output terminal (344);
a ground terminal;
a first thin-film transistor (TFT) (308P) having a control terminal, a first current terminal, and a second current terminal, the second current terminal of the first TFT (308P) coupled to the supply terminal and the control terminal of the first TFT (308P) coupled to the first voltage and coupled to the first input terminal (302);
a second TFT (312P) having a control terminal, a first current terminal, and a second current terminal, the second current terminal of the second TFT (312P) coupled to the first current terminal of the first TFT (308P), the control terminal of the second TFT (312P) coupled to the second voltage, and the first current terminal of the second TFT (312P) coupled to the first output terminal (344);
a third TFT (328P) having a control terminal, a first current terminal, and a second current terminal, the second current terminal of the third TFT (328P) coupled to the ground terminal and the control terminal of the third TFT (328P) coupled to the bias voltage and coupled to the first input terminal (302); and
a fourth TFT (332P) having a control terminal, a first current terminal, and a second current terminal, the second current terminal of the fourth TFT (332P) coupled to the first current terminal of the third TFT (328P), the control terminal of the fourth TFT (332P) coupled to the fourth voltage, and the first current terminal of the fourth TFT (332P) coupled to the first output terminal (344).

16. The apparatus of claim 15, wherein the bias circuit (350) further includes:
a first adjustable current source (358) coupled to the second diode connected transistor (360); and
a second adjustable current source (356) coupled to the third diode connected transistor (354).

17. The apparatus of claim 15, wherein the first output terminal (344) is coupled to a receiver circuit (112).

18. The apparatus of claim 15, further including a serializer circuit (104) to convert a plurality of input signals into a single input signal.

19. The apparatus of claim 18, wherein the input signals are video input signals.

20. The apparatus of claim 15, wherein the bias circuit (350) further includes a fifth diode connected transistor coupled to the second diode connected transistor (360), the fifth diode connected transistor to supply a fifth voltage.
